(19) United States
(12) Patent Application Publication
(10) Pub. No.: US 2013/0141287 A1
(43) Pub. Date: Jun. 6, 2013

(54) Apparatus for Measuring a Radiation Pattern of an Active Antenna Arrangement

(71) Applicant: Jorma Tapio Pallonen, Kirkkonummi (FI)

(72) Inventor: Jorma Tapio Pallonen, Kirkkonummi (FI)

(73) Assignee: Nokia Siemens Networks Oy, Espoo (FI)

(21) Appl. No.: 13/642,148

(22) PCT Filed: Sep. 30, 2010
(86) PCT No.: PCT/EP2010/064550

§ 371 Date: Feb. 5, 2013

(30) Foreign Application Priority Data
Apr. 22, 2010 (EP) PCT/EP2010/055327

(51) Int. Cl. G01R 29/10

(52) U.S. Cl. CPC G01R 29/10
USPC 343/703

(57) ABSTRACT

An apparatus for measuring a radiation pattern of an active antenna arrangement is provided, where the active antenna arrangement includes one or more radios having dedicated antenna elements in communication with each other. The apparatus has a common module external to the active antenna arrangement and a calibration radio, which is also external to the active antenna arrangement and coupled to the common module. The common module includes a transmit/receive unit and interfacing means for interfacing the common module with the active antenna arrangement, with the calibration radio and with a network node. The common module further includes a measurement device for measuring signals received from the active antenna arrangement.

### FIELD OF THE INVENTION

The invention generally relates to an apparatus for measuring a radiation pattern of an active antenna arrangement. More particularly, the invention relates to measurement of the radiation pattern of an active antenna arrangement using a near field measurement method.

### BACKGROUND OF THE INVENTION

In a wireless communications system, when several co-ordinated radios associated to a common signal each connected directly to only a few antenna elements per radio are operating together, a larger antenna array is formed. There is an optimum radiation pattern and sensitivity that this antenna array should have.

The radiation patterns of a few antenna elements specific to one radio can easily be measured separately when the antenna elements are not connected to the radio. Any near or far field antenna measurement system can be used. This, however, is not sufficient when it is required to optimise the radiation pattern either at the user or cell level, since the most important performance improvement by the active antennas comes from the whole phased array formed by the radios and the individual antenna elements together when they are forming a common illumination function for the large array. The performance and functionality of the whole active antenna array must be measured and verified as a single entity both in development and also in production.

There are two main known categories for antenna radiation pattern measurement: near field measurement and far field measurement.

Near field measurement is based on the fact that the radiation pattern of any antenna can be calculated when the illumination function of the antenna is measured at any closed surface around the antenna. This requires measurement of relative power and relative phase at a sufficient number of points, so that when the Discrete Fourier Transformation (DFT) is calculated for the measured illumination function points, the result gives the radiation pattern with the relative resolution to the measured illumination function. The theory behind this is well-known and there are several commercial devices that can measure the illumination function either in spherical, cylindrical or Cartesian coordinates. Using any basic coordinate surface simplifies DFT calculation. A near field measurement system fits easily indoors, can be easily isolated from the external interference and is typically lower in price compared to a far field measurement system. In addition, the reflection level of the anechoic chamber for a near field system can be significantly higher than the reflection level of the chamber for far field test system. That is because of the lower attenuation between the reference antenna and the antenna under test so that reflections cause a smaller error in the result.

A typical near field measurement system has a control unit to steer scanning, to interface the commercial test equipment that is performing the phase and power measurement —typically a network analyzer—and a mechanical or combined electrical and mechanical scanning system. The control unit also resolves the radiation pattern by calculating the DFT of the measurement results. The interfaces from the control unit to the scanning system are typically proprietary but the interface from the test equipment is typically either IEEE 488 or more commonly Ethernet.

FIG. 1 shows a known near field system with electrical scanning around one of the axis. The electrical scanner is no more complex than a ring of “inside looking” antennas of which one or more can be selected with a switch and connected to the one test port of the network analyzer. Each antenna represents an individual measurement point. The other test port is connected to the antenna under test. The network analyzer can now measure both relative phase and power at each point. Movement of the scanner ring in the transverse direction is either performed by a rotator that turns the DUT antenna in the centre point of the scanner ring or a linear actuator that moves the antenna under test along the Z-axis of the ring.

Far field measurement is the traditional way of finding out the radiation pattern of the antenna. Measuring only the relative received power using the reference antenna is sufficient and also the positioning system is very simple. The problem with far field measurement is that the distance R between the antenna under test and the reference antenna must be bigger than the far field limit of the antenna under test; i.e.,

R=2d²/λ

In which:
d=largest dimension of the antenna
λ=wavelength.

The far field limit can be about 20 to 40 m for typical telecommunications antennas and hence also for typical active antennas.

The consequence of this is that the far field ranges are typically outdoor ranges and the distance between the reference antenna and antenna under test typically varies from 50 metres to several hundreds of metres. Outdoor located far field ranges are becoming a rare facility nowadays because, in addition to the problem of adverse weather conditions limiting the usage of the outdoor test ranges, the telecommunications networks may interfere with or be interfered by the measurements of the antennas. It is possible to locate far field antenna test ranges to indoor conditions only if either the anechoic chamber is longer than the far field limit, or if a special large mirror is used to fold the radiation beam so that the far field conditions are reached at a shorter distance. The chamber has to be roughly half the length of that reduced distance. However, these options are typically very costly. The chamber is large and vastly expensive to manufacture, and the cost of a large and difficult to manufacture mirror may also have to be added.

Therefore, near field measurement is the preferred option for active antennas. The problem is that there is no existing equipment or method to measure both the relative power and the relative phase of the signal of any telecommunications active antennas. There is no test equipment available, which is able to detect the modulated signals of telecommunications radios or to send them modulated signals so that they can be detected. Relative power can be measured using this available test equipment, but there are no means to measure the phase, hence the near field measurement cannot be performed. The only commercial test equipment that can measure both power and phase is a network analyzer. However, it is impossible to use this equipment for measuring active antennas.

An effective solution is thus required for the measuring the near field radiation pattern of active antennas.

### SUMMARY OF THE INVENTION

Accordingly, the invention provides an apparatus for measuring a radiation pattern of an active antenna arrangement, where the active antenna arrangement can include one or more radios, each coupled to one or more radiating dedicated antenna elements. The apparatus includes a common module external to the active antenna, as well as a calibration radio, which is also external to the active antenna and coupled to the common module. The common module has a phase and amplitude calibration signal transmit/receive unit, interfacing means for interfacing the common module with the active antenna arrangement, with the calibration radio and with a network node. Further, the common module includes a measurement device for measuring the calibration signals received from the active antenna arrangement.

The active antenna arrangement under test interfaces with the common module, which measures signals received from the active antenna arrangement (antenna(s) coupled to the one or more radios included in the active antenna arrangement). The measured signals are then processed to obtain a radiation pattern generated by the active antenna arrangement. This apparatus provides that the common module is external to the active antenna arrangement and is connectable to the active antenna under test using an interface that is carrying digital the IQ-data image of the RF signal either received at or to be transmitted by the active antenna arrangement. In this way, the near field radiation pattern of the active antenna arrangement can be solved for both transmission and reception.

The measurement device may include a signal generator for generating a test signal for transmission by the calibration radio. The signal generator may generate a proper test signal vector to be transmitted by the active antenna arrangement (radio provided inside the active antenna) or by the calibration radio.

The measurement device may further include a comparator for comparing two test signals transmitted by the active antenna arrangement and received by the calibration radio. For example, the comparator may compare at least two test signals at a time transmitted by active antenna radios, which are received by the calibration radio.

Preferably, the comparator is further adapted to compare relative phases and powers of signals received by at least two radios provided in the active antenna arrangement.

Advantageously, the measurement device may include a data copying device for copying a signal transmitted by the active antenna arrangement and adjusting its amplitude and phase. The downlink data stream for each active antenna may be copied by the data copying device. Furthermore, the data copying device may adjust the amplitude and phase individually of the copied downlink data stream from each active antenna.

The invention also provides a measurement system including an antenna arrangement having one or more radios with dedicated antenna elements in communication with each other. The measurement system also has an apparatus for measuring a radiation pattern of the antenna arrangement. The apparatus includes a common module external to the active antenna arrangement and a calibration radio external to the active antenna arrangement, which is coupled to the common module. The common module includes a transmit/receive unit, an interfacing means for interfacing with the active antenna arrangement, with the calibration radio and with a network node, and a measurement device for measuring signals received from the active antenna arrangement.

The invention further provides a method of measuring a radiation pattern of an active antenna arrangement including one or more radios having dedicated antenna elements in communication with each other. The method comprises interfacing an external common module to the active antenna arrangement, to a calibration radio, and to a network node, measuring signals received from the active antenna arrangement using the common module, and processing the measured signals to obtain the radiation pattern.

Preferably the method further includes coupling the common module to an external near field measurement device.

The invention will now be described, by way of example only, with reference to specific embodiments, and to the accompanying drawings, in which:

### BRIEF DESCRIPTION OF THE DRAWINGS

FIG. 1 shows a conventional apparatus for measuring a radiation pattern of an antenna arrangement;

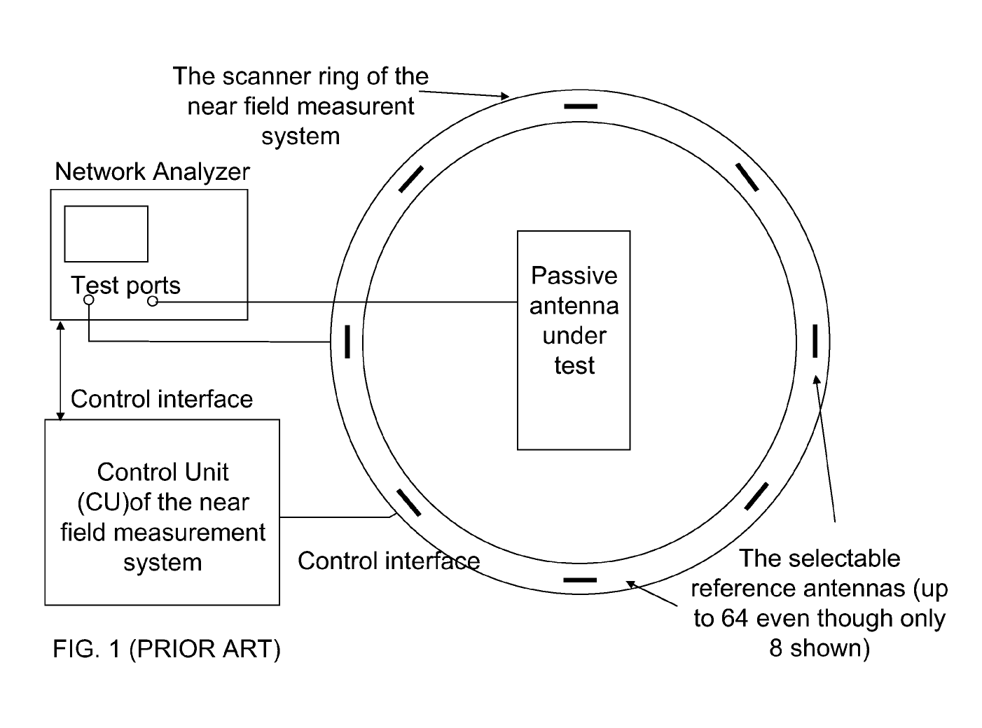

FIG. 2 is a simplified schematic diagram of an apparatus for measuring a radiation pattern of an antenna arrangement according to an embodiment of the invention; and

FIG. 3 is a simplified schematic diagram of a communications system including an apparatus for measuring a radiation pattern of an antenna arrangement according to an embodiment of the invention.

### DETAILED DESCRIPTION OF EXEMPLARY EMBODIMENTS

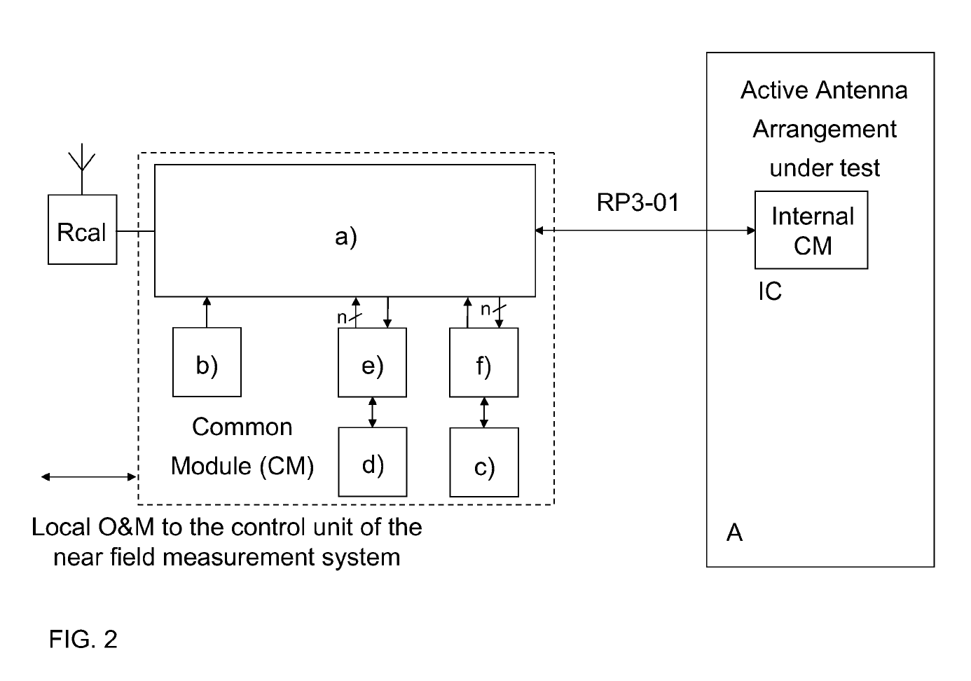

FIG. 2 shows a measurement apparatus for measuring a radiation pattern of an active antenna arrangement A under test according to the invention. The active antenna arrangement includes individual radios having dedicated antenna elements in communication with each other.

The measurement apparatus includes a common module CM, calibration radio Rcal and calibration probe; i.e., an antenna. A calibration antenna inside the active antenna arrangement A can be replaced by other means to arrange the physical feedback from every individual active antenna radio to the calibration radio Rcal.

The calibration radio Rcal may either be a modified BTS radio with the uplink and downlink frequencies reversed, or it can be a modified mobile phone radio with an interface allowing it to be connected to the common module CM. The antenna connected to the calibration radio Rcal represents the reference antenna of a near field measurement system.

The common module CM includes a widely configurable multiplexer-de-multiplexer switch a) for interfacing and arranging an interface in between with each single active antenna radio (R1−Rn), the Rcal and the base band processing unit of the BTS. The switch a) can switch between digital synchronous serial interfaces I, for example OBSAI RP3-01 and CPRI buses, which are the best known industrial options for such synchronous serial interfaces. However, other serial interfaces could be used.

The common module CM also includes a signal generator b) for generating a proper test signal vector to be transmitted by each individual active antenna radio or by the Rcal. A first comparator c) is provided in the common module CM for comparing the relative phases and powers received by at least two active antenna radios at a time and a second comparator d) is provided for comparing at least two test signals transmitted by the active antenna radios and received by the Rcal at a time.

A data copying device e) inside the common module CM is adapted to copy the downlink (DL) data stream for each active antenna radio and adjust its amplitude and phase individually and a processor f) is adapted to take in the received IQ data stream from each individual active antenna radio, adjust the phase and power of each received IQ data stream separately and form a combined data stream of them as a vector sum of the individual data streams.

The common module CM may also have a connector (not shown here) for local connection to any computer based system for test and development purposes. This connector may be implemented by either USB, Ethernet or any serial interfaces. Ethernet is the preferred bus for that purpose.

The above-described components are provided externally to the antenna under test. These components measure the relative power and phase of the signals and connect them to the control and RF interfaces of a commercial near field measurement system so that the relative phase in each measurement point can be detected both in transmission and reception.

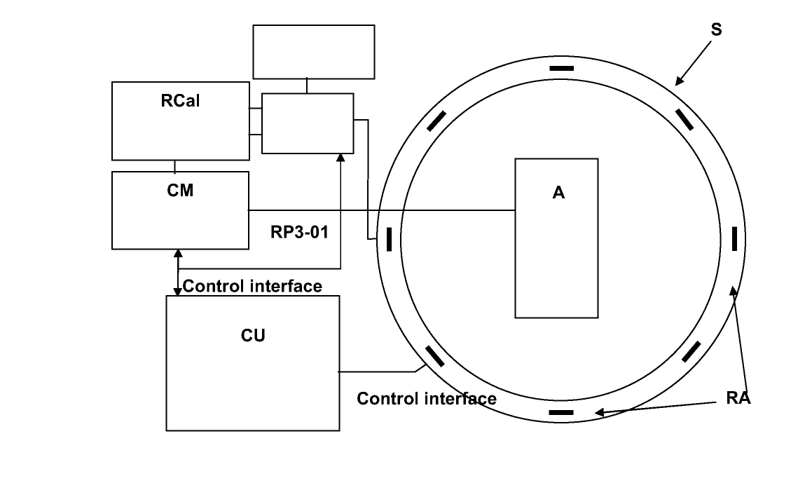

FIG. 3 shows a measurement system implementing the above-described apparatus. The common module CM and an additional calibration radio Rcal are connected to the active antenna arrangement A under test, to the control unit CU of a commercial near field test system and to the RF interface of a scanner ring S of the commercial near field test system. In this setup the measurement apparatus according to the invention (external calibration radio Rcal and the external common module CM) replace the network analyzer that is used for passive antennas. The external common module CM in the measurement apparatus is connected to the active antenna A under test using an interface, e.g. a RP3-01 interface, which carries the digital IQ-data image of the RF signal either received or to be transmitted. The RP3-01 interface also carries all O&M-data between the common module CM in the measurement apparatus and the common module in the active antenna A. The O&M data includes all commands, acknowledgments and also measurement results when required.

The measurement procedure happens as follows (the interface RP3-01 shown can be also be replaced by any other RF-BB bus):

The interface RP3-01 of the active antenna A under test, which would normally be connected to a Base Band Processing Unit in a BTS, is first connected to one of the RP3-01 interfaces of the external common module CM of the measurement apparatus. That can be either the BB side or radio side interface depending on the setup of the external common module CM. The purpose of this connection is to establish both O&M and RF-BB IQ-data links between the external common module CM of the measurement apparatus and the common module inside the active antenna A. The external common module CM is provided with a specialized SW and firmware for communicating with the common module internal to the active antenna and also with the near field test system control unit. The internal common module of the antenna A operates practically in the same manner as in normal active antenna operation. It first performs a calibration procedure that is required to ensure that the radiation pattern generated by the active antenna is as required. In this case the internal common module is provided with a measurement mode in which the external common module CM is able to command it. In this measurement mode, the internal antenna common module does not require data from the base band processing in the base band processing unit but uses the calibration signals as received and transmitted signals and is also able to communicate sufficiently with the external common module CM.

After the common module CM in the measurement apparatus has performed a standard calibration routine both the common modules (the common module CM in the measurement apparatus and the common module inside the active antenna arrangement A) start sending IQ-data to their own transmitters: the internal common module sends the data to all the radios in the active antenna arrangement with the timing pattern verified in calibration and the external common module CM to its own calibration radio Rcal. At the same time the external common module CM starts receiving the IQ-data from all the active antenna receivers in the active antenna arrangement and the external CM from its own calibration radio Rcal. This enables uplink and downlink calibration to happen at the same time. The radios in the active antenna arrangement A operate as in the normal operation according to the preset phase and power pattern; i.e., they display an Illumination Function typical of the desired radiation pattern. The control unit of the near field systems selects the radiation pattern and commands it to the internal common module in the active antenna arrangement A via the external common module CM in the measurement apparatus.

When all the required data links are established and the active antenna arrangement A under test is operating as in normal use, the measurement procedure can start. The control unit of the measurement system selects the desired measurement point using its positioning system either by selecting the correct reference antenna element RA of the scanner (detector) ring S (the scanner ring S may include up to sixty four selectable reference antennas) or physically moving/rotating the active antenna arrangement A under test or moving the reference antenna RA, or performing more than one of the above procedures in a specific manner to the system.

At each measurement point the external CM receives a test signal generated by the signal generator in the internal common module and distributed to each radio by the interface between the internal CM and the radios inside the active antenna arrangement A. The signals from the individual radios are combined in air between the reference antenna of the antenna test system and the radio specific antennas of the active antenna arrangement. This combined signal forms in the measurement point a well defined value of the illumination function. Because the interface a) and the data link between the two common modules are of the same type, and because they are synchronous and able to maintain identical timing at both the sending and receiving ends, it is possible to fix the timing between both the internal common module in the active antenna A and external common module CM provided in the measurement apparatus with sufficient accuracy for relative radio signal phase measurement by the comparator d). The comparator d) in the external common module CM compares the signal as it is when generated by the signal generator b), before it is formed by the data copying device e) of the common module internal to the active antenna A, because this signal represents the total transmitted radio signal that is the correct reference for the radiation pattern measurement.

The relative power can also be measured by the comparator d). The required phase lock in the comparator d) can be maintained for a long enough time to measure all the required points of the illumination function. That the required phase lock can be maintained may be derived from the basic functional requirements of an active antenna arrangement A. The comparator d) is better for measuring the relative power than the comparator c) because there are two separate data streams to be compared with each other, not a single stream containing two different signals to be distinguished and compared.

After all the points are measured, the relative power and phase values of each point can be communicated to the control unit of the antenna test system and it can calculate the radiation pattern in transmission.

After the radiation pattern in transmission is measured, the roles of the common module CM in the measuring apparatus external to the antenna A and the common module inside the active antenna A are reversed and the radiation pattern in reception is measured.

The external common module CM starts generating the test signal vector using the signal generator b) and distributes it to its own calibration radio Rcal to be transmitted through the (selected) reference antenna of the near field test system to be received by the individual radios in the active antenna arrangement.

The propagation of that signal between the reference antenna and the individual radio specific antennas in the active antenna arrangement A is reciprocal to the propagation in transmission. That same signal is copied also to the common module internal to the active antenna A and the phase accuracy of the transmitted and received signal by the external common module CM in the measurement apparatus and that in the antenna A is maintained according to the same principles as in transmission measurement.

The individual radios of the active antenna arrangement

A each receive the signal transmitted by the reference antenna separately. The data processing device f) combines the received individual signals so that the resultant represents the total signal typical of each radiation pattern. The total signal is a correct power and phase reference for a relative comparison with the signal generated by the external common module CM. This comparison is performed in the common module internal to the active antenna A by the comparator d) and the result is sent via the RF-BB bus between the common modules to the external CM.

When all the points have measured, the relative power and phase values of each point are communicated to the control unit of the antenna test system and it can calculate the radiation pattern in reception.

In this way, the radiation pattern of the active antenna is solved in both transmission and in reception. The reference data to the active antenna under test and to the target radiation pattern with that specific radiation pattern can be added to the measurement result file and can be archived. Furthermore, the difference between the target and measured radiation patterns can be calculated. The measurement can then be repeated with another target radiation pattern for the same active antenna.

Although the invention has been described hereinabove with reference to specific embodiments, it is not limited to these embodiments, and no doubt further alternatives will occur to the skilled person that lie within the scope of the invention as claimed.

1. An apparatus for measuring a radiation pattern of an active antenna arrangement including one or more radios having dedicated antenna elements in communication with each other, the apparatus comprising:
a common module external to the active antenna arrangement; and
a calibration radio external to the active antenna arrangement and coupled to the common module,
wherein the common module includes
a transmit/receive unit,
interfacing means for interfacing the common module with the active antenna arrangement, with the calibration radio and with a network node, and
a measurement device for measuring signals received from the active antenna arrangement.

2. The apparatus according to claim 1, wherein the measurement device includes a signal generator for generating a test signal for transmission by the calibration radio.

3. The apparatus according to claim 1, wherein the measurement device includes a comparator for comparing two test signals transmitted by the active antenna arrangement and received by the calibration radio.

4. The apparatus according to claim 3, wherein the comparator is further adapted to compare relative phases and powers of signals received from at least two dedicated antenna elements.

5. The apparatus according to claim 1, wherein the measurement device includes a data copying device for copying a signal transmitted by the active antenna arrangement and adjusting its amplitude and phase.

6. A measurement system, comprising:
an active antenna arrangement including one or more radios having dedicated antenna elements in communication with each other; and
an apparatus for measuring a radiation pattern of the antenna arrangement, the apparatus including
a common module external to the active antenna arrangement, and
a calibration radio external to the active antenna arrangement and coupled to the common module,
wherein the common module includes a transmit/receive unit, interfacing means for interfacing with the active antenna arrangement, with the calibration radio and with a network node, and a measurement device for measuring signals received from the active antenna arrangement.

7. A method of measuring a radiation pattern of an active antenna arrangement including one or more radios having dedicated antenna elements in communication with each other, the method comprising:
interfacing an external common module to the active antenna arrangement, to a calibration radio, and to a network node;
measuring signals received from the active antenna arrangement using the common module; and
processing the measured signals to obtain the radiation pattern.

8. The method according to claim 7, further comprising coupling the common module to an external near field measurement device.

9. The method according to claim 7, wherein the step of processing takes place in the network node.
